(19) United States
(12) Patent Application Publication
(10) Pub. No.: US 2004/0025336 A1
(43) Pub. Date: Feb. 12, 2004

(54) No profile rework system heat control

(76) Inventor: Robert Hugh Patrick, Lockeford, CA (US)

Correspondence Address: Robert H. Patrick, PO BOX 64, Lockeford, CA, 95237, US

(21) Appl. No.: 10/458,017

(22) Filed: Jun. 9, 2003

Related U.S. Application Data
(60) Provisional application No. 60/394,362, filed on Jul. 9, 2002.

(51) Int. Cl. H05K 3/34

(52) U.S. Cl. 29/840; 29/851; 29/843

(57) ABSTRACT

A component removal and replacement system heat control mainly used in reworking surface mount components such as BGA's that uses electronic circuits to bring the component to reflow without using a profile. By monitoring the actual temperatures of the printed circuit board and the component to control the amount of heat provided to their surfaces while using the added circuitry to compensate for different boards and components it allows reworking with out the need for profiles either manually or automatically generated.

### CROSS-REFERENCE TO RELATED APPLICATIONS

Provisional Patent application No. 60/394,362

### FEDERALLY SPONSORED RESEARCH

Not Applicable

### SEQUENCE LISTING OF PROGRAM

Not Applicable

### BACKGROUND OF INVENTION—FIELD OF INVENTION

This invention relates to the control of the heating process used to rework printed circuit boards, Specifically the automatic control of the heat sources used to remove and replace components from the PCB during the rework process.

### BACKGROUND OF INVENTION

The present invention relates generally to the heat control of an apparatus used to remove and replace components on a printed circuit board. The invention uses both analog circuits and digital logic to control the amount of heat and time to prevent thermal shock of the components while increasing the heat until the solder holding the component to the printed circuit board reaches liquidus. This invention removes the need to profile the component and board combination for reworking a printed circuit board when removing or placing a component.

It can be appreciated that reworking systems devices have been used to remove components and replace components for years. Typically a trial run is made with a generic profile to determine how much heat should be applied over what period of time to ensure the heat does not increase at a rate that exceeds that which can be tolerated by the component and printed circuit board. Through this method a profile is created which can be used every time that specific component is removed or replaced on that or an identical printed circuit board. A similar prior art allows for the automatic creation of a profile by “testing” the heating response of the component and automatically deriving a profile that can be used, saved and later be fine-tuned for optimum results.

There are many problems with the existing systems. The first problem is the need to create a profile that is specific to the many variables incurred in the rework process. Such variables include but are not limited to, the ambient temperature, the composition of the printed circuit boards and the composition of the components being reworked. Most of these variables are not known or obvious when the rework is being done.

The second problem occurs when the rework process depends on the trial and error method of creating these profiles. Components and printed circuit boards can be damaged from thermal shock and excessive heat during this process.

A third problem exists because the operator input could be wrong and the damage caused may not be known until many months later.

In these respects this invention departs from the conventional systems since it incorporates electronic circuitry to assure the temperatures of the component and the printed circuit board are monitored, the monitors input the information to controls that continuously adjust the heat sources so the component and the printed circuit board are heated at a controlled rate until the solder binding the component to the PCB is at liquidus. The controlled rate can be set depending on the thermal shock tolerated by the component and the printed circuit board. The thermal shock tolerance ratings are made available from the component and PCB manufacturers.

In view of the foregoing disadvantages inherent in the known types of rework systems methods of bring a component's solder to reflow now present in prior art, the present invention provides a new system that overcomes the problems of establishing profiles by eliminating their need.

The general purpose of the present invention, which will be described in greater detail, is to provide a rework system that does not require the need to create profiles to remove or replace a component.

To attain this, the present invention generally comprises analog and digital circuitry to control the heat source energy over time. Certain provisions are incorporated to emulate the operator's input to ensure the process follows what would be an accurate profile. Using this invention no profile is saved since each time the process is started the variables that must be considered are processed automatically. These variables would include the current temperature of the printed circuit board, the rate of heat absorption of the printed circuit board and the rate of heat absorption of the component being reworked.

The operator determines the overall conditions that can be set. The degrees per second, the maximum printed circuit board temperature and the reflow temperature of the solder used with the component being removed or replaced.

The present invention allows for the use of preset degrees per second for the board temperatures and the component reflow temperature. Further to these the operator can override these temperatures while the process is underway.

The present invention also provides an automatic “pause” function to stop the rate per second clock should any one of the surfaces being heated not follow the degree per second temperature increase or decrease. The pause automatically is removed when the expected heat is with approximately 4 degrees Celsius of what is expected.

When the process is started the temperature of the component being removed or replaced, the top and the bottom of the printed circuit board are all monitored. Using this information the heating process starts at the coldest reading sensed by “fast forwarding’ the clock to that temperature to reduce the reworking process time.

During the rework process the heat and time are manipulated to provide the fastest rework possible using the heat available without causing thermal shock.

### SUMMARY

A primary object of the present invention is to provide a method to rework printed circuit boards without the possibility of damaging the component on one hand or the printed circuit board on the other.

Another object of this invention is to have the process described above to be automatic

Another object of this invention is to rework boards by semi-skilled operators.

Another object of this invention is it can be added to existing systems

Another object of this invention is to eliminate the need to create profiles as are now needed in rework systems.

To accomplish the above and related objects, this invention may be embodied in the form illustrated in the accompanying block diagram drawings and that changes may be made in the specific logic blocks. The invention can be accomplished utilizing linear logic, hybrid logic or software programming.

### DRAWINGS—FIGURES

FIG. 1 is a block diagram of the circuit used to control the heat source outputs

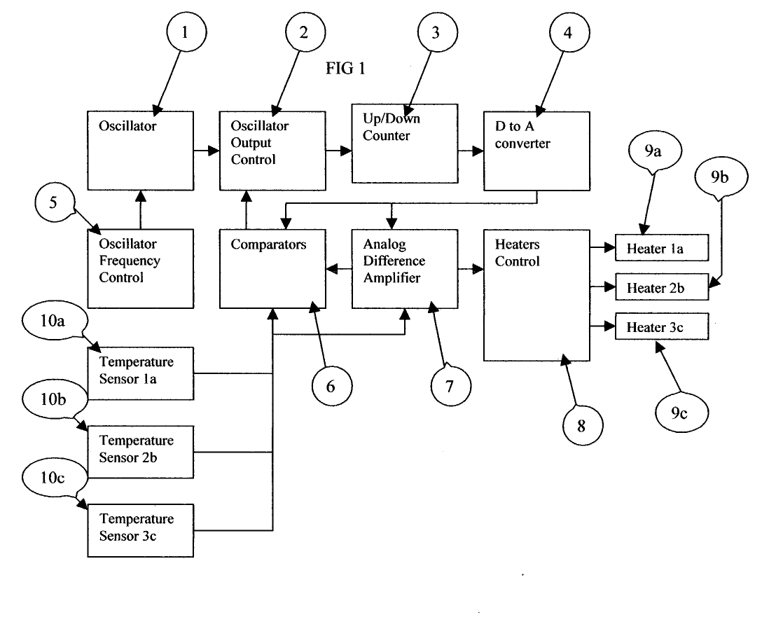

### DETAILED DECRIPTION OF THE DESIGN—FIG. 1

Turning now descriptively to the drawing in which similar reference characters denote similar elements through out, the attached drawing illustrates the “no profile system”.

To provide for a no profile rework system the following considerations must be met. The rate of temperature change must be controlled so as not to exceed the degrees Celsius per second determined by the component or PCB thermal shock tolerance. The normal thermal shock tolerance is at this time is from 1 degree Celsius to 3 degrees Celsius per second. This thermal tolerance applies to both the heating and cooling process. A second condition is the need to control the process so the time needed can be extended should the heat available not be sufficient t to meet the desired temperature in the time specified. In order to supply suffiencent heat energy to the component and the printed circuit board the capability of controlling three heaters should considered. The heaters could be any kind that provide the heat, resistive, infrared or laser. One heater should cause the component to reach a temperature that allows the solder used to affix it to the printed circuit board to reach liquidus, the other heaters should be able to heat both the top and bottom of the printed circuit board to a controlled temperature in a range tolerated by the printed circuit board material and the components it is populated with.

The first requirement is to generate a voltage that represents a temperature increase or decrease in degrees per second. To accomplish this an oscillator (1) programmed by the Oscillator Frequency Control (5) to run at a frequency that combined with the up/down counter is converted to a digital format that in turn is input to a digital to analog converter whose output increases or decreases in Millivolts per second. For an output of 10 Millivolts per second the oscillator in (1) would be set to run at 10 Hz. The output would increase the 12-bit counter (3) by 10 counts per second. In one second the digital output would reach binary 10. The binary output is then input to a 12-bit D to A converter (4) with a reference voltage of 4.096 volts. The 12 bit data provides 4096 increments of the 4.096 volts so each increment is 0.001 volts. Therefore 10 clock inputs to the counter create an analog voltage at the output of the D to A of 10 Millivolts. If the oscillator (1) were continually connected to this circuit the output of the D to A (4) would increment by 10 Millivolt per second. If the counter were in the Down mode the output of the D to A converter (4) would decrease at the same rate. If the oscillator frequency is doubled the rate of increase doubles to 20 Millivolts per second. For the purpose of this design the oscillator frequency is set so the output of the D to A converter to be equal to or less than the thermal shock tolerance limit of the component being reworked or the printed circuit board it is associated with. The D to A converter output relationship to temperature is 10 Millivolts are equal to 1 degree Celsius. Therefore if the thermal shock tolerance of a component or board being heated or cooled were 3 degrees Celsius per second the oscillator (1) would be set to run at 30 Hz.

The Oscillator Frequency Control (5) provides two functions. The first function is to allow the operator to select the oscillator frequency depending on the thermal shock tolerance. Using an spst push button switch that sets a latch that in turn causes a high on the coinciding setting of the oscillator IC does this. The component used to demonstrate the design is an Epson SPG 8651A programmable oscillator. The frequency select pins were used per the specification for the frequencies required.

The second function is to select a setting in the oscillator (1) that increases the frequency by 1000 when the system start switch is closed through a latch. This latch is reset when the output of the D to A converter (4) is compared in the comparators (6) to the coldest temperature measured by the temperature sensors (10a, 10b, 10c) in Millivolts where 1 Millivolt is equal to 1 degree Celsius. There is one comparator per temperature sensor and when any one of the three comparators sense the two signals are equal the comparator output goes high which is diode coupled to the latch reset which resets the latch. At this time the previously selected frequency of the oscillator (1) is output. The purpose of this circuit is to have the rework process time reduced by not starting at 0 degrees Celsius or some other arbitrary temperature.

The next circuit is the Comparators (6). The comparators used to increase the frequency are explained above. The other comparators provide control of the oscillator output (1) causing it to be stopped or directed to the UP input on the UP/Down counter (3) or the down input of the Up/Down counter (3). There are comparators to sense when the reflow temperature is reached and to sense when the desired board temperature has been reached. There is also a comparator that is used to stop the process.

Pause Circuit

When the output of a sensor, converted to 1 Millivolt is equal to 1 degree Celsius is input to a analog difference amplifier and the D to A converter (4) is input to the other input and the output multiplied by 10 this output is compared by a comparator with the reference input being the set to the allowable difference such as 5 degrees which would, in this case be 0.5 volts. When the difference between the actual temperature as measured by the temperature sensors (10 is more than the allowable difference between the desired temperature which is the output of the D to A converter (4) and the actual temperature being the output of the temperature sensor (10a, 10b, 10c) the comparator output goes high and is input to a gate when the other input of the gate is the output of the Oscillator (1). When the comparator output is low the oscillator (1) output is connected to the up/down control (2). When the comparator output is high the oscillator (1) output is blocked in effect pausing the rework process time. When all temperature sensors (10a, 10b, 10c) are reading temperatures that differ less than the allowable Millivolts (10 Millivolts equals 1 degree Celsius) from the output of the A to D converter (4) the difference amplifiers (7) output are less than the allowable temperature difference in 1 degree Celsius equals 10 Millivolt and the comparator (6) output goes low.

Heating/Cooling Control

When the process is started the output of the oscillator (1) passes through the pause gate to two more gates. One of these gates output is connected to the UP input of the UP/Down counter. The other gate's output is connected to the DOWN input.

The other inputs are opposite; one being high while the other one through an inverter is low. When the voltage sensed at the component sensor (10a) is input to a comparator (6) and the voltage at the other input is preset to the temperature required to cause reflow, in Millivolts, the output goes high and causes the two gate inputs to reverse by inputting one directly to a down gate input and through the inverter to the up gate input. This in effect causes the counter to count down which in effect causes the voltage at the output of the D to A converter to decrease.

When the voltage sensed at either board sensors (10b) or (10c) is input to an analog comparator (6) and the voltage at the other input is preset to the temperature established for the printed circuit board in Millivolts through a SPDT analog relay the comparator output goes to the coil of the analog relay. When the SPDT analog relay is energized by the high the preset temperature is connected to the difference amplifiers (7) associated with the respective circuit causing the temperature of the printed circuit board to remain at that preset temperature that is the maximum temperature allowed for the PCB.

The heater control (8) controls the power applied to each of the heaters (9a, 9b, 9c) individually. The difference outputs mentioned above used to generate the PAUSE is also used to control the power to the heaters. When the temperature sensor voltage output (10a, 10b, 10c) associated with the respective heater (9a, 9b, 9c) is less than the D-A output (4) it causes the power to increase. Conversely, if the temperature sensor voltage output associated with a heater is more the D to A output the power to that heater is reduced.

Operation

The invention provides for the control of heat on a component related to a printed circuit board and the printed circuit board.

When START is pressed a switch applies a high to a R/S latch. The output places a high on the clock enable input allowing its output. It also put a high on the reset input of the D to A converter (3) and the UP/DOWN Counter (3) This output is controlled as described above.

When the temperature is decreasing a comparator senses when it is below 150 degrees Celsius causing a high at it's output which is input to the R/S latch reset input causing it's output to go low stopping the clock and resetting the D to A converter (4) and the Up/down counter (3).

Potentiometers are used to manually set the reflow temperature and the printed circuit board temperature. Switches are used to select the degrees per second rate heating and cooling as well as the stop and start functions.

What is claimed is:

1. A method of reworking a printed circuit board without requiring a profile comprising the steps of:
Providing a voltage that will increases or decrease at a rate selectable to represent the thermal shock tolerance of a component being removed or placed. This voltage corresponds to the degrees per second tolerance of the component or the PCB it is associated with, which ever is less. This voltage is changed using feedback from temperatures sensors monitoring the targets being heated by heat sources controlled by the voltage and modified as required. A plurality of heaters are controlled, usually three, with one for the heater used to heat the component and two for heaters to heat the top and bottom of the PCB.

2. The method of claim 1 wherein the voltage created in claim 1 is caused to stop changing should a temperature sensor voltage output indicate that the heated subject is less than the temperature required at that time. The heating continues and when all temperatures reach the required temperature the time component of process is allowed to proceed. Therefore the process is paused until the heater heats the component and the PCB top and bottom to the temperature required for that time period.
The method of claim 1 wherein the voltage created in claim 1 is replaced with a fixed voltage representing the temperature established for the PCB when the sensors monitoring the PCB indicate this temperature has been reached. The allows the PCB to remain at that temperature until the voltage when decreasing reaches that temperature where it reverts back to the voltage created in claim 1. Therefore the board is heated to a temperature and is held at that temperature until the process, when decreasing the voltage representing the degrees per second is at the temperature established for the PCB at which time that voltage regains control over the heater control for the PCB

3. The method of claim 1 wherein the voltage created in claim 1 is caused to decrease at the same rate it was increasing when the voltage reaches a value that represents the reflow temperature. At this time the voltage created in claim 1 is caused to stop changing for a predetermined period of time or a time selected by the operator This step would be likened to the DWELL in a rework system

4. The method of claim 1 wherein the voltage created and changed by claim 2 and 4 is used to control the heater used to heat the component.

5. The method of claim 1 wherein the voltage created and changed by claim 3 and 4 are used to control the heaters used to heat the PCB.
